(19) United States
(12) Patent Application Publication
(10) Pub. No.: US 2019/0067631 A1
(43) Pub. Date: Feb. 28, 2019

(54) ORGANIC LIGHT EMITTING DIODE PACKAGE STRUCTURE, ELECTRONIC DEVICE AND PACKAGING METHOD

(71) Applicants: BOE TECHNOLOGY GROUP CO., LTD., Beijing (CN); Chengdu BOE Optoelectronics Technology Co., Ltd., Sichuan (CN)

(72) Inventors: Wei GUO, Beijing (CN); Yuanjie XU, Beijing (CN); Zhonglin CAO, Beijing (CN); Pengcheng ZANG, Beijing (CN); Shiqi CHEN, Beijing (CN)

(21) Appl. No.: 15/988,042

(22) Filed: May 24, 2018

(30) Foreign Application Priority Data
Aug. 25, 2017 (CN) 201710742113.2

(51) Int. Cl. H01L 51/52; H01L 51/50

(52) U.S. Cl. CPC H01L 51/5246; H01L 51/5253; H01L 51/5012; H01L 51/5221; H01L 51/5206

(57) ABSTRACT

An organic light emitting diode package structure, an electronic device and a packaging method are disclosed. The organic light emitting diode package structure includes a first substrate, a second substrate, and an organic light emitting diode device. The second substrate is disposed opposite to the first substrate. The organic light emitting diode device is disposed between the first substrate and the second substrate. At least one of the first substrate and the second substrate is provided with a groove, and the groove is disposed on the surface of the first substrate facing the second substrate or/and the surface of the second substrate facing the first substrate. The organic light emitting diode device is sealed in the groove.

### CROSS-REFERENCE TO RELATED APPLICATIONS

The present application claims priority to Chinese Patent Application No. 201710742113.2, titled “ORGANIC LIGHT EMITTING DIODE PACKAGE STRUCTURE, ELECTRONIC DEVICE AND PACKAGING METHOD” and filed on Aug. 25, 2017, the entire contents of which are incorporated herein by reference.

### TECHNICAL FIELD

At least one embodiment of the present disclosure relates to an organic light emitting diode package structure, an electronic device, and a packaging method.

### BACKGROUND

Due to the advantages such as self-luminescence, high brightness, wide viewing angles, high contrast, and low power consumption of Organic Light emitting Diodes (OLEDs), OLEDs have received increasing attention and have been gradually applied to mobile phone screens, computer monitors, and full-color televisions. The organic material layer of the OLED can emit light when being energized, but many organic materials are sensitive to moisture and oxygen and are not resistant to high temperature. In addition, the oxidation of the metal electrode of the OLED device also degrades the performance of the organic light emitting diode. Therefore, isolating the organic light emitting diodes from oxygen, water, and the like is important for extending the life of the device. The organic light emitting diode device is generally sealed with a sealant and a cover plate, and the tightness of the seal is very important.

### SUMMARY

At least one embodiment of the present disclosure provides an organic light emitting diode package structure including: a first substrate, a second substrate and an organic light emitting diode device. The second substrate is opposite to the first substrate; and the organic light emitting diode device is disposed between the first substrate and the second substrate; a groove is disposed on at least one of the first substrate and the second substrate, the groove is disposed on at least one of a surface of the first substrate facing the second substrate and a surface of the second substrate facing the first substrate, and the organic light emitting diode device is sealed in the groove.

For example, in the organic light emitting diode package structure, a first groove is disposed on the first substrate, and the organic light emitting diode device is disposed in the first groove.

For example, in the organic light emitting diode package structure, a first groove is disposed on the first substrate, and a second groove is disposed on the second substrate at a position corresponding to the first groove, and the first groove and the second groove are opposite to each other; and at least a first part of the organic light emitting diode device is located in the first groove.

For example, in the organic light emitting diode package structure, a second part of the organic light emitting diode device is located in the second groove.

For example, in the organic light emitting diode package structure, a surface of the organic light emitting diode device facing the second substrate is substantially flush with a surface of the first substrate facing the second substrate.

For example, the organic light emitting diode package structure further includes: a protective layer disposed over the organic light emitting diode device and covering the organic light emitting diode device.

For example, in the organic light emitting diode package structure, a material of the protective layer includes one of a metal oxide and a non-metal oxide.

For example, the organic light emitting diode package structure further includes: a sealing layer filled between the organic light emitting diode device and the first substrate and the second substrate, and covering the organic light emitting diode device.

For example, the organic light emitting diode package structure further includes: a sealant frame disposed between the first substrate and the second substrate and bonding the first substrate and the second substrate.

For example, the organic light emitting diode package structure further includes: a glass adhesive disposed between the first substrate and the second substrate at a side of the sealant frame close to an edge of the second substrate, and bonding the first substrate and the second substrate.

For example, in the organic light emitting diode package structure, the first substrate is a base substrate, and the second substrate is a package cover.

At least one embodiment of the present disclosure also provides an electronic device including any one of the above organic light emitting diode package structures.

At least one embodiment of the present disclosure also provides a packaging method including: providing a first substrate and a second substrate; forming a groove on at least one of the first substrate and the second substrate, wherein the groove is disposed on at least one of a surface of the first substrate facing the second substrate and a surface of the second substrate facing the first substrate; providing an organic light emitting diode device on the first substrate; and pressing the second substrate and the first substrate together such that the organic light emitting diode device is encapsulated in the groove.

For example, in the packaging method, the forming a groove on at least one of the first substrate and the second substrate includes: forming the groove on the first substrate.

For example, in the packaging method, the forming a groove on at least one of the first substrate and the second substrate includes: forming the groove on the second substrate.

For example, in the packaging method, the forming a groove on at least one of the first substrate and the second substrate includes: forming a first groove on the first substrate; and forming a second groove on the second substrate at a position corresponding to the first groove.

For example, the packaging method further includes: forming a sealing layer on the organic light emitting diode device such that the sealing layer is filled between the organic light emitting diode device and the first substrate and the second substrate, and covers the organic light emitting diode device.

For example, the packaging method further includes: forming a sealant frame and a glass adhesive in a peripheral region of the second substrate; melting the glass adhesive; and curing the sealant frame and the glass adhesive.

### BRIEF DESCRIPTION OF THE DRAWINGS

In order to more clearly illustrate the technical solutions of the embodiments of the present disclosure, the following will briefly describe the drawings of the embodiments. Apparently, the drawings in the following description merely relate to some embodiments of the present disclosure, but do not limit the present disclosure.

FIG. 1 is a schematic cross sectional view of an organic light emitting diode package structure;

FIG. 2 is a schematic plan view of an organic light emitting diode package structure provided by an embodiment of the present disclosure;

FIG. 3 is a schematic cross sectional view taken along line I-I′ in FIG. 2;

FIG. 4 is another schematic cross sectional view taken along line I-I′ in FIG. 2;

FIG. 5 is yet another schematic cross sectional view taken along line I-I′ in FIG. 2;

FIG. 6 is a schematic diagram of a display device according to an embodiment of the present disclosure;

FIGS. 7A to 7F are schematic diagrams of a packaging method for an organic light emitting diode provided by an embodiment of the present disclosure;

FIGS. 8A to 8F are schematic diagrams of another packaging method for an organic light emitting diode provided by an embodiment of the present disclosure; and

FIGS. 9A to 9F are schematic diagrams of yet another packaging method for an organic light emitting diode provided by an embodiment of the present disclosure.

### DETAILED DESCRIPTION

To make the objectives, technical solutions, and advantages of the embodiments of the present disclosure clearer, the following clearly describes the technical solutions of the embodiments of the present disclosure with reference to the accompanying drawings of the embodiments of the present disclosure. Apparently, the described embodiments are a part of the embodiments of the present disclosure, rather than all the embodiments. All other embodiments obtained by a person of ordinary skill in the art based on the described embodiments of the present disclosure without creative efforts shall fall within the protection scope of the present disclosure.

Unless otherwise defined, technical or scientific terms used herein should be commonly understood as having a common knowledge in the field to which the present disclosure belongs. The terms “first”, “second” and the like used in the description and the claims of the present disclosure do not indicate any order, quantity, or importance, but merely used to distinguish between different components. The terms “including” or “comprising” and the like means that an element or item preceding the word encompasses an elements or item and their equivalents listed after the word, without excluding other elements or items. “Inside”, “outside” and the like are only used to indicate relative positional relationship. When the absolute position of the described object is changed, the relative positional relationship may also be changed accordingly.

The drawings used in the present disclosure are not drawn strictly in actual scale, and the number of light emitting diode devices in the organic light emitting diode package structure is not limited to the number shown in the figures, and the specific size and number of each structure may be determined based on actual needs. The drawings described in this disclosure are merely schematic structural diagrams.

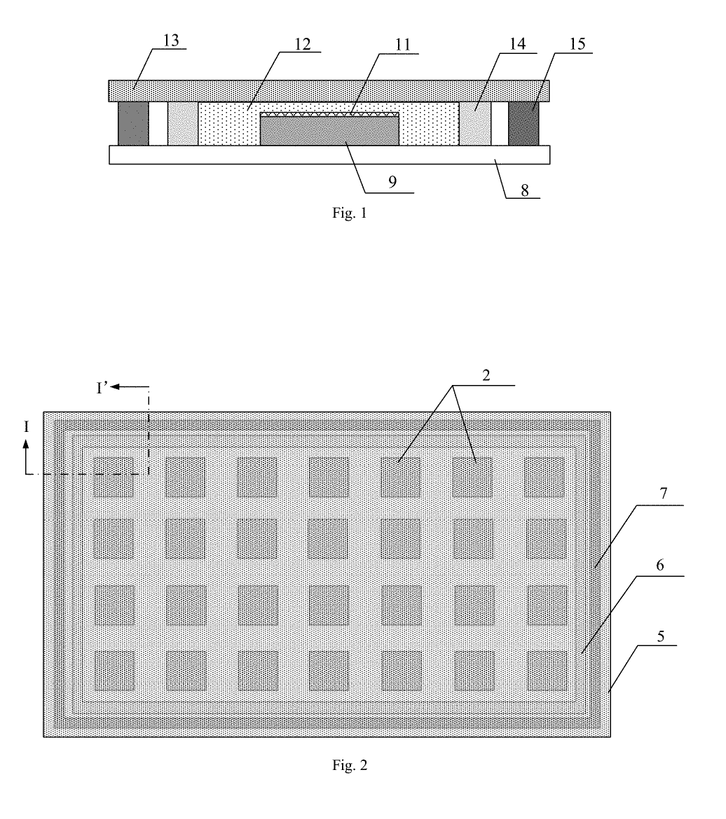

FIG. 1 is a schematic plan view of an organic light emitting diode package structure. As shown in FIG. 1, the organic light emitting diode package structure includes a base substrate 8, a package cover 13, an organic light emitting diode device 9, and a sealing layer 12. The package cover 13 is disposed opposite to the base substrate 8. The organic light emitting diode device 9 is disposed on a flat surface of the base substrate 8 facing the package cover 13, between the base substrate 8 and the package cover 13. The sealing layer 12 is located between the base substrate 8 and the package cover 13, and covers the organic light emitting diode device 9 and a part of the base substrate 8 to achieve the sealing of the organic light emitting diode device 9 and prevent external moisture, oxygen, heat and the like from coming into contact with the organic light emitting diode device 9 and causing damage. The organic light emitting diode package structure further includes a protective layer 11, a sealant frame 14 and a glass adhesive 15. The protective layer 11 is disposed over the organic light emitting diode device 9 to prevent moisture, oxygen, heat, and the like intruding into the protective layer 12 from coming into contact with the organic light emitting diode device 9. The sealant frame 14 and the glass adhesive 15 are disposed between the base substrate 9 and the package cover 13 for bonding the base substrate 8 and the package cover 13 while preventing external moisture, oxygen, heat, and the like from intruding into the interior of the organic light emitting diode package structure. However, the sealing layer of the organic light emitting diode package structure does not seal the organic light emitting diode device 9 tightly enough, and there may still be gaps between the sealing layer of the organic light emitting diode package structure and the organic light emitting diode device 9, causing external light, oxygen, and heat to intrude from such gaps into and be in contact with the organic light emitting diode device 9, and thus shortening the service life of the organic light emitting diode 9. In addition, since the internal structure of the organic light emitting diode package is incompact and has gaps, the mechanical strength of the structure is low. In addition, in such organic light emitting diode package structure, the distance between the base substrate 8 and the package cover 13 is relatively large, resulting in a large thickness of the organic light emitting diode package structure and consumption of a large amount of sealing material, sealant frame and glass adhesive.

At least one embodiment of the present disclosure provides an organic light emitting diode package structure, including a first substrate, a second substrate, and an organic light emitting diode device. The second substrate is disposed opposite to the first substrate. The organic light emitting diode device is disposed between the first substrate and the second substrate. At least one of the first substrate and the second substrate is provided with a groove, and the groove is disposed on the surface of the first substrate facing the second substrate and/or the surface of the second substrate facing the first substrate. The organic light emitting diode device is sealed in the groove.

At least one embodiment of the present disclosure further provides an electronic device including the above organic light emitting diode package structure.

At least one embodiment of the present disclosure also provides a packaging method for an organic light emitting diode. The method includes: providing a first substrate and a second substrate; forming a groove on at least one of the first substrate and the second substrate, with the groove located on the surface of the first substrate facing the second substrate and/or the surface of the second substrate facing the first substrate; providing an organic light emitting diode device on the first substrate; and pressing the second substrate and the first substrate together with respect to each other, such that the organic light emitting diode device is encapsulated in the groove.

The structures, methods, and technical effects involved in the present disclosure will be described in detail through several specific embodiments.

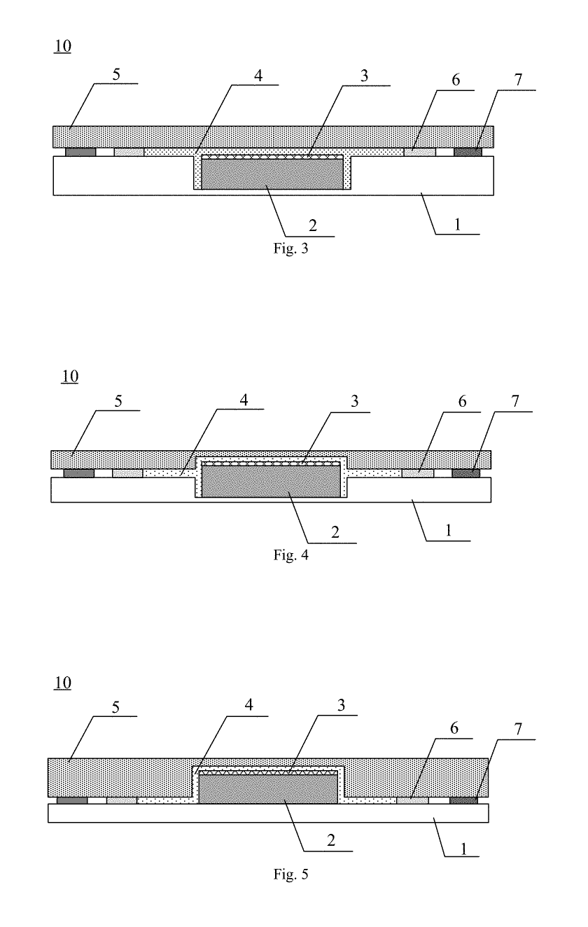

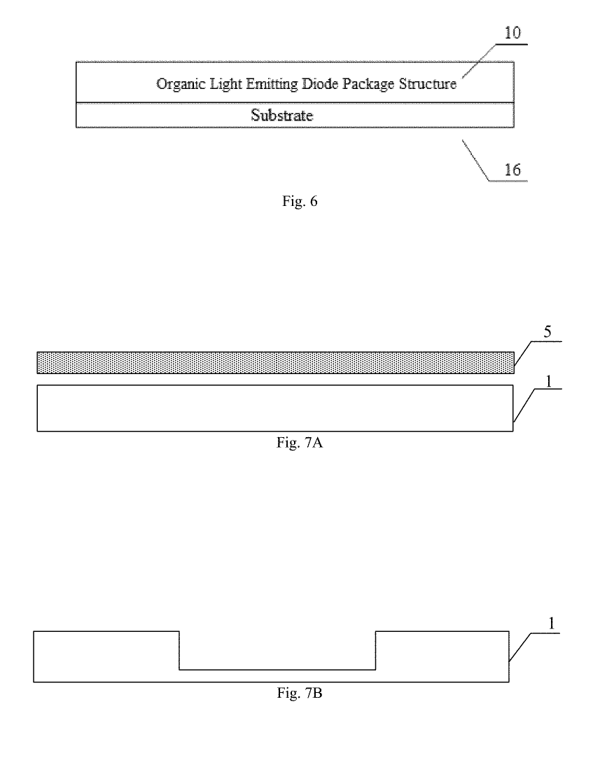

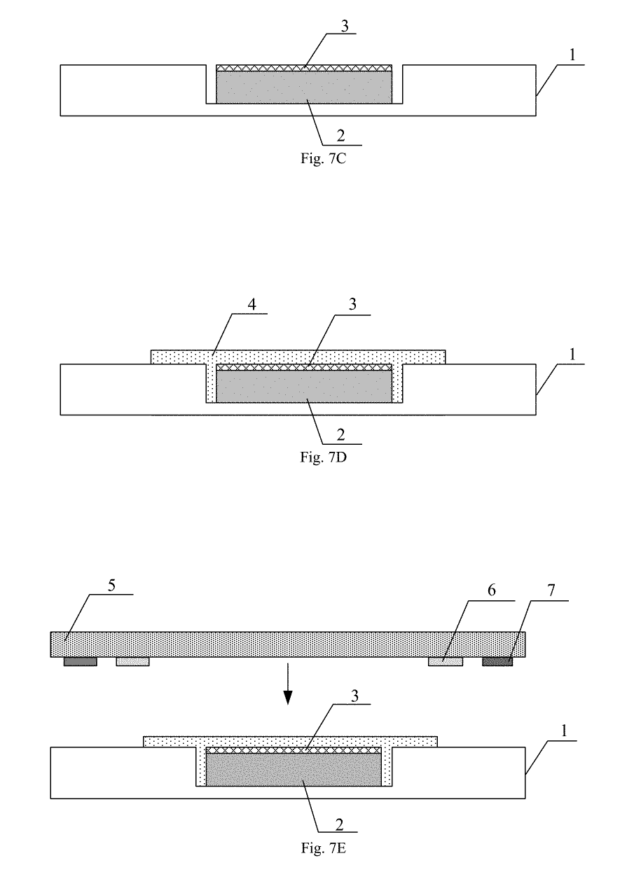

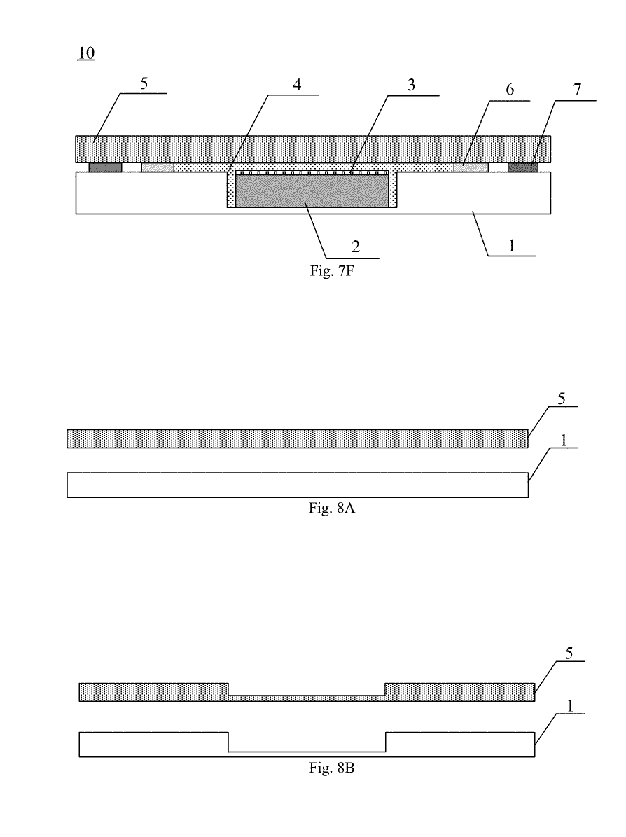

FIG. 2 is a schematic plan view of an organic light emitting diode package structure provided by an embodiment of the present disclosure. FIG. 3 is a schematic cross sectional view taken along line I-I′ in FIG. 2. FIG. 4 is another schematic cross sectional view taken along line I-I′ in FIG. 2. FIG. 5 is yet another schematic cross sectional view taken along line I-I′ in FIG. 2.

The present embodiment provides an organic light emitting diode package structure including: a first substrate, a second substrate, and an organic light emitting diode device. The second substrate is disposed opposite to the first substrate. The organic light emitting diode device is disposed between the first substrate and the second substrate. A groove is disposed on at least one of the first substrate and the second substrate, and the groove is disposed on the surface of the first substrate facing the second substrate and/or the surface of the second substrate facing the first substrate. The organic light emitting diode device is sealed in the groove.

For example, a first groove may be provided on the first substrate, and the organic light emitting diode device is disposed in the first groove. For example, as shown in FIG. 3, the organic light emitting diode package structure 10 includes a first substrate 1, a second substrate 5, and an organic light emitting diode device 2. A first groove is disposed on the surface of the first substrate 1 facing the second substrate 5, and the organic light emitting diode device 2 is disposed in the first groove. The second substrate 5 is disposed opposite to the first substrate 1, for example, the second substrate 5 is disposed in parallel to the first substrate 1, to seal the organic light emitting diode device 2 between the first substrate 1 and the second substrate 5. Compared with a structure in which the organic light emitting diode device 2 is disposed on a flat surface of the substrate, the organic light emitting diode package structure 10 can have a tighter seal to the organic light emitting diode device 2. Also it can effectively reduce the thickness of the organic light emitting diode package structure, which facilitates the production of thin and light devices such as light and thin light sources and display devices.

For example, the organic light emitting diode package structure 10 may further include a sealing layer 4. The sealing layer 4 is filled between the organic light emitting diode device 2 and the first substrate 1 and the second substrate 5, and covers the organic light emitting diode device 2. For example, as shown in FIG. 3, a part of the sealing layer 4 is filled between the second substrate 5 and the upper sides of the organic light emitting diode device 2 and the first substrate 1, covering the surface of the organic light emitting diode device 2 facing the second substrate 5 and a part of the first substrate 1. The other part of the sealing layer 4 is located in the first groove and is filled between the organic light emitting diode device 2 and the sidewall of the first groove. As a result, the organic light emitting diode device 2 can be more tightly sealed. Moreover, since the interior of the organic light emitting diode package structure is sealed more tightly and has reduced gaps, the organic light emitting diode package structure can have a higher mechanical strength.

For example, the sealing layer 4 may include a functional filling material, which may include a moisture absorbing material, an oxygen absorbing material, and/or a heat dissipating material, and the like. Many organic light emitting materials included in organic light emitting devices easily react with water and oxygen to affect their performance, and the oxidization of the metal electrodes thereof may degrade the function of the organic light emitting diodes. Also, the organic material does not tolerate high temperature, so the sealing layer 4 including the moisture absorbing material, the oxygen absorbing material, and/or the heat dissipating material can prevent the organic light emitting diode device 2 from contacting invading moisture and oxygen (e.g., air or other oxidizing gas, etc.), and can also assist heat dissipation, which is conducive to prolong the service life of the organic light emitting diode device 2. For example, the moisture absorbing material may be a desiccant such as quicklime (CaO) or a water absorbing resin; the oxygen absorbing material may be an inorganic oxygen absorbing agent such as metal powder (including iron powder, copper powder, etc.), mixture of hypo and iron powder, or sodium dithionite, etc., and may also be an organic oxygen absorbent such as butylated hydroxyanisole (BHA) or butylated hydroxytoluene (BHT); and the heat dissipating material may be a heat conduction grease such as heat dissipating particles made of zinc oxide, aluminum oxide, boron nitride and the like. However, in the present embodiment, the functional filling material included in the sealing layer 4 is not limited to the above-mentioned three kinds of moisture absorbing material, oxygen absorbing material, and heat dissipating material, but may also include other materials that are favorable for protecting the organic light emitting diode device 2. The above three kinds of materials are not limited to those listed, and the present disclosure is not limited thereto.

For example, the surface of the organic light emitting diode device 2 facing the second substrate 5 is substantially flush with the surface of the first substrate 1 facing the second substrate 5. In this way, the sealing layer 4 can cover the organic light emitting diode device 2 evenly. On the one hand, it can obtain a better sealing effect, and on the other hand, it can reduce the distance between the first substrate 1 and the second substrate 5, thereby reducing the material consumption amount for the sealing layer and thus lowering the production cost.

For example, the organic light emitting diode package structure 10 may further include a protective layer 3. The protective layer 3 is disposed over the organic light emitting diode device 2 and covers the organic light emitting diode device 2. For example, the protective layer 3 may be an inorganic thin film layer, and may be formed of a metal oxide (aluminum oxide, titanium dioxide, or the like) or a non-metal oxide (silicon oxide or silicon nitride, etc.) material. The protective layer 3 can prevent water vapor and/or oxygen invading the sealing layer 4 from contacting the light emitting diode device 2 and causing damage to the light emitting diode device 2, and thus can further protect the light emitting diode device 2. It should be noted that the material of the protective layer 3 is not limited to the types set forth above.

For example, the organic light emitting diode package structure 10 may further include a sealant frame 6 disposed between the first substrate 1 and the second substrate 5 for bonding the first substrate 1 and the second substrate 5. The sealant frame 6 forms a sealed space with the first substrate 1 and the second substrate 5, and the sealing layer 4, the protective layer 3, and the organic light emitting diode device 2 are sealed in the sealed space to provide shockproof and dust proof. For example, a variety of suitable organic adhesives (for example, epoxy resin, etc.) can be selected for the sealant frame 6. The sealant frame 6 may also include the above-mentioned functional filling materials, which may further have functions of waterproof, oxygen-proof, heat dissipating, and the like. In addition, the sealant frame 6 of the organic light emitting diode package structure 10 may not be limited to a single layer, and the material of each layer may be the same or different. In this regard, the sealant frame 6 may be designed for the purpose of achieving better effects of water and oxygen proof

For example, the organic light emitting diode package structure 10 further includes a glass adhesive 7. The glass adhesive 7 is disposed between the first substrate 1 and the second substrate 5, and is located on the side of the sealant frame 6 close to the edge of the second substrate 5, and also functions to bond the first substrate 1 and the second substrate 5. The glass adhesive 7 is disposed on the side of the sealant frame 6 close to the edge of the second substrate 5, so that it may have a bonding function, and at the same time, it may further seal the organic light emitting diode device, which prevents the substance bad for the organic light emitting diodes in the external environment from entering into the interior of the organic light emitting diode package structure. The glass adhesive 7 may also include the functional filling materials described above, so as to further have the functions of waterproof, oxygen-proof, heat dissipating, and the like.

The above example is a case where a groove is only disposed on the first substrate, and grooves may also be provided on both the first substrate and the second substrate. For example, FIG. 4 shows an example of another organic light emitting diode package structure. The organic light emitting diode package structure 10 differs from the above example in that a first groove is disposed on the surface of the first substrate 1 facing the second substrate 5, a second groove is disposed on the surface of the second substrate 5 facing the first groove, at a position corresponding to the first groove, and the first groove and the second groove are opposite to each other. At least a first part of the organic light emitting diode device 2 is located in the first groove. For example, as shown in FIG. 4, it is possible that the first part of the organic light emitting diode device 2 is located in the first groove and the second part of the organic light emitting diode device 2 is located in the second groove. In this way, the organic light emitting diode device 2 may be sealed in the first groove and the second groove. For example, in the present example, a sealing layer 4 may also be filled between the first substrate 1 and the second substrate 5. A part of the sealing layer 4 is located in the first groove and the second groove, filled in gaps between the sidewalls of the first groove and the second groove and the organic light emitting diode device 2, and covers the entire organic light emitting diode device 2. Another part of the sealing layer 4 covers a part of the first substrate 1 to achieve sealing of the organic light emitting diode device 2. This structure can more tightly seal the organic light emitting diode device 2 in the groove and thus better protect the same, and also provide the organic light emitting diode package structure with higher mechanical strength. However, in other examples, it is possible that the entire organic light emitting diode device 2 is located in the first groove, and only a part of the sealing layer 4 is filled in the second groove.

In the example shown in FIG. 4, the organic light emitting diode package structure 10 may also include a protective layer 3, a sealant frame 6 and a glass adhesive 7. The structures and materials thereof are the same as those in the example shown in FIG. 3, and may refer to the above description. At the same time, the organic light emitting diode package structure can also achieve the effect of reducing the consumption amount of sealing layer material, sealant frame, and glass adhesive.

For example, it is also possible to provide a groove only on the second substrate. For example, the organic light emitting diode package structure 10 shown in FIG. 5 is different from the above example in that the second substrate 5 is disposed opposite to the first substrate 1, and a second groove is disposed on the surface of the second substrate 5 facing the first substrate 1. The organic light emitting diode device 2 is disposed between the first substrate 1 and the second substrate 5 and sealed in the second groove. A part of the sealing layer 4 is disposed in the second groove, filled in gaps between the sidewalls of the first and second grooves and the organic light emitting diode device 2, and covers the entire organic light emitting diode device 2. Another part of the sealing layer 4 covers a part of the first substrate 1, to seal the organic light emitting diode device 2. The technical effects of this example and other structures not mentioned are the same as those in the previously described example, and may refer to the previous description.

In the organic light emitting diode package structure of this embodiment, for example, the first substrate may be a base substrate, and the second substrate is a package cover. For example, the base substrate includes a driving circuit for driving the organic light emitting diode device, for example, including a power line or the like. For example, the base substrate may further include a gate line, a data line, a switching transistor, a driving transistor, a storage capacitor, and the like. The package cover may be a glass substrate, a plastic substrate, or the like.

It should be noted that the organic light emitting diode package structure provided in this embodiment may include one or more organic light emitting diode devices, and each light emitting diode device may be configured as described above. For example, in FIG. 2, the organic light emitting diode package structure includes a plurality of light emitting diode devices 2 arranged in an array, forming a planar structure as a whole, which can be applied to a device that requires an entire surface to emit light. The organic light emitting diode device includes, for example, an anode, an organic light emitting layer, and a cathode stacked in this order. In operation, electrons are injected from the cathode, holes are injected from the anode, and the electrons and the holes are combined in the organic light emitting layer and then are excited to emit light. If necessary, a hole injection layer and a hole transport layer may be provided from the anode to the organic light emitting layer, and an electron injection layer and an electron transport layer may be further provided from the cathode to the organic light emitting layer. For example, the anode usually employs a conductive material with a high work function such as indium tin oxide (ITO); the cathode usually employs a conductive material with a low work function such as a metal of Ag, Al, Ca, In, Li, and Mg, or a composite metal with a low work function (e.g., Mg—Ag magnesium silver) and the like. The organic light emitting diode device may emit red light, green light, blue light, white light and the like during operation. For example, a fluorescent layer or a color filter, etc. may be disposed on the light emitting side of the organic light emitting diode device in order to adjust the color of the light.

The organic light emitting diode package structure provided in this embodiment can be applied to, for example, a display device, a lighting device (for example, a lighting lamp), and the like, and is particularly suitable for manufacturing a thin and light type device.

An embodiment of the present disclosure provides an electronic device including any one of the above-mentioned organic light emitting diode package structures. For example, the electronic device may be a display device, a lighting device, or the like.

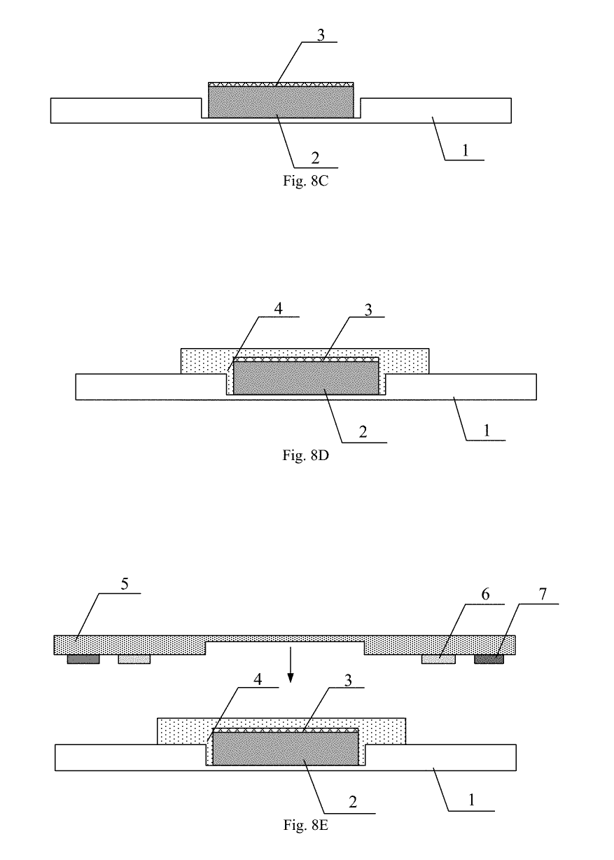

For example, FIG. 6 is a schematic diagram of a display device provided by this embodiment. As shown in FIG. 6, the organic light emitting diode package structure 10 may be disposed above the substrate 16. For example, the substrate 16 may be a TFT substrate, a driving circuit board, or the like. The organic light emitting diode device of the organic light emitting diode package structure 10 is located in the pixel area of the display device. The example shown in FIG. 6 is a bottom emission display device. In other examples, the display device may be a top emission type or a double emission type.

It should be noted that, the present embodiment only shows the structure related to the organic light emitting diode package structure, and other structures can be designed by those skilled in the art according to the conventional technology.

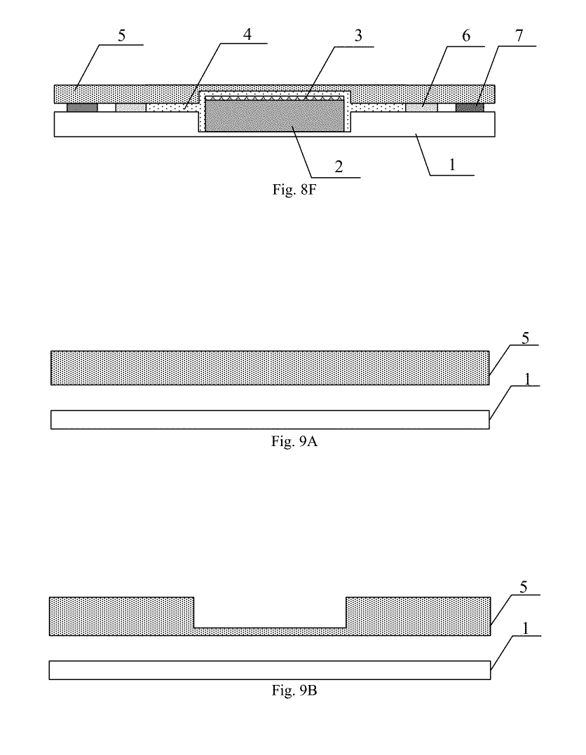

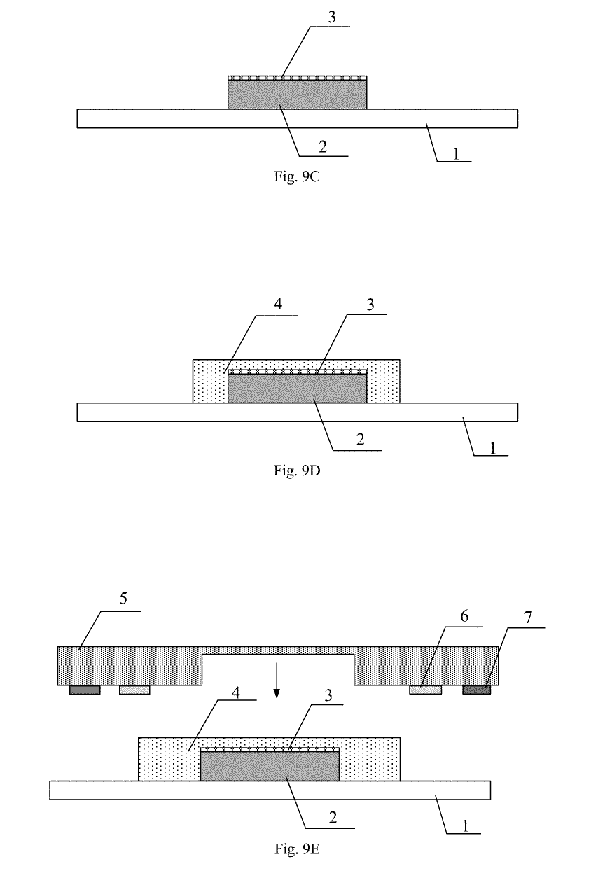

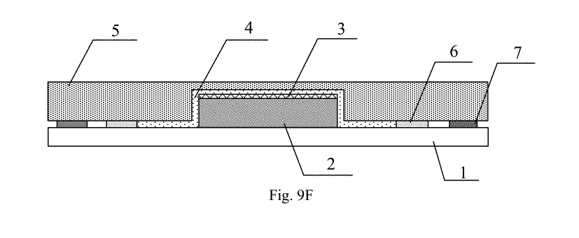

FIGS. 7A to 7F are schematic diagrams of a packaging method for an organic light emitting diode provided by an embodiment of the present disclosure. FIGS. 8A to 8F are schematic diagrams of another packaging method for an organic light emitting diode provided by an embodiment of the present disclosure. FIGS. 9A to 9F are schematic diagrams of yet another packaging method for an organic light emitting diode provided by an embodiment of the present disclosure.

The present embodiment provides a method for packaging an organic light emitting diode (OLED). The method includes: providing a first substrate and a second substrate; forming a groove on at least one of the first substrate and the second substrate; providing an organic light emitting diode device on the first substrate; and pressing the second substrate and the first substrate together, such that the organic light emitting diode device is encapsulated in the groove.

For example, encapsulating the organic light emitting diode device in the groove may include: forming the groove on the first substrate and placing the organic light emitting diode device in the groove. For example, as shown in FIG. 7A, a first substrate 1 and a second substrate 5 are provided. As shown in FIG. 7B, a first groove is formed on the first substrate 1. For example, an acid etching process such as a hydrofluoric acid etching process may be adopted. Alternatively, an engraving machine may be employed for engraving. For example, the engraving can be performed by programming the engraving machine to control the position, shape, and depth of the carved groove. Alternatively, a method of embossing a softened resin substrate and then curing the same may be employed. For example, the depth of the first groove may be made substantially the same as the thickness of the organic light emitting diode device 2.

As shown in FIG. 7C, the organic light emitting diode device 2 is disposed in the first groove. Each functional layer of the organic light emitting diode device can be formed by a suitable method, such as chemical vapor deposition, physical vapor deposition (e.g., evaporation, sputtering, etc.), ink jet printing, photolithography, etc., which will not be described herein.

A protective layer 3 is formed on the organic light emitting diode device 2. For example, the protective layer 3 may be deposited by vapor deposition, magnetron sputtering, ion plating, chemical vapor deposition (CVD) or the like. However, the method of forming the protective layer 3 is not limited to the above methods, and a person skilled in the art can select according to the materials adopted. For the material of the protective layer 3, details may refer to the description in the above embodiment, which will not be repeated herein.

For example, as shown in FIG. 7D, the method may further include forming a sealing layer 4 on the organic light emitting diode device 2, such that a part of the sealing layer 4 is disposed over the organic light emitting diode device 2 and the first substrate 1, and covers the surface of the organic light emitting diode device 2 facing the second substrate 5, and a part of the first substrate 1, and another part of the sealing layer 4 is disposed in the first groove, filled between the organic light emitting diode device 2 and the sidewall of the first groove. As a result, the sealing layer 4 covers the organic light emitting diode device 2. In this way, the organic light emitting diode device 2 can be more tightly sealed. For example, in the case where the depth of the first groove and the thickness of the organic light emitting diode device 2 are substantially the same, the sealing layer 4 can cover the organic light emitting diode device 2 with a flat surface, which may improve the sealing.

For example, as shown in FIG. 7E, the method further includes forming a sealant frame 6 and a glass adhesive 7 in a peripheral region of the surface of the second substrate 5 facing the first substrate 1. For example, the sealant frame 6 may be formed by dispensing or the like. After heating the glass adhesive 7 to melt the same, as shown in FIG. 7E, the first substrate 1 and the second substrate 5 are pressed together, such that the organic light emitting diode device 2 is encapsulated in the first groove, and the sealing layer 4 is filled between the organic light emitting diode device 2 and the first substrate 1 and the second substrate 5 after the packaging.

The method also includes curing the sealant frame 6 and the glass adhesive 7. For example, the sealant frame 6 and the glass adhesive 7 are cured after the first and second substrates 1 and 5 are pressed together. For example, a UV irradiation curing or heating curing method may be adopted. In this embodiment, the curing method is not limited. The specific curing method can be determined by those skilled in the art according to the type of the sealant frame and the glass adhesive employed and the properties thereof. For the materials of sealant frame and glass adhesive, details may refer to the description in the above embodiment. The organic light emitting diode package structure 10 as shown in FIG. 7F may be formed with the above method.

The organic light emitting diode package structure 10 formed by the method can tightly seal and thus commendably protect the organic light emitting diode device 2 in the groove, therefore the organic light emitting diode package structure may have a high mechanical strength. Moreover, the organic light emitting diode package structure can also reduce the consumption amount of sealing layer material, sealant frame, and glass adhesive.

For example, the encapsulating the organic light emitting diode device in the groove may also include: forming a first groove on the first substrate; placing at least a first part of the organic light emitting diode device in the first groove; and forming a second groove on the second substrate at a position corresponding to the first groove; and pressing the second substrate and the first substrate together with respect to each other, such that the first groove and the second groove are aligned and the organic light emitting diode device is encapsulated in the first groove and the second groove that are aligned. For example, as shown in FIG. 8A, a first substrate 1 and a second substrate 5 are provided. As shown in FIG. 8B, a first groove is formed on the first substrate 1, and a second groove is formed on the second substrate 5 at a position corresponding to the first groove. For the formation method, details may refer to the description in the above examples, such that the depth of the first groove is smaller than the thickness of the organic light emitting diode. As shown in FIG. 8C, the organic light emitting diode device 2 is disposed in the first groove, such that a first part of the organic light emitting diode device is located in the first groove, that is, the first part of the organic light emitting diode device is placed in the first groove. A protective layer 3 is formed on the organic light emitting diode device 2. The material and formation method of the protective layer 3 in this embodiment are the same as that in the above examples, and details may refer to the above description.

As shown in FIG. 8D, a sealing layer 4 is formed on the organic light emitting diode device 2, such that the sealing layer 4 covers the organic light emitting diode device 2.

As shown in FIG. 8E, the second substrate 5 formed with the sealant frame 6 and the glass adhesive 7 is pressed against the first substrate 1 such that the first groove and the second groove are aligned, to package the organic light emitting diode device 2 in the aligned first and second grooves. The formation of the sealant frame 6 and the glass adhesive 7 in this embodiment is the same as the method in the above example. After the sealant frame 6 and the glass adhesive 7 are cured, the organic light emitting diode package structure as shown in FIG. 8F is formed. The structures, methods, and effects not mentioned in this example are the same as those in the above example.

For example, the encapsulating the organic light emitting diode device in the groove may also include: forming the groove on the second substrate and disposing the organic light emitting diode device on the first substrate such that the organic light emitting diode device is located in the groove after the second substrate and the first substrate are pressed together with respect to each other. For example, as shown in FIG. 9A, a first substrate 1 and a second substrate 5 are provided. As shown in FIG. 9B, a second groove is formed on the second substrate 5. For example, the depth of the second groove may be made substantially the same as the thickness of the organic light emitting diode device.

As shown in FIG. 9C, the organic light emitting diode device 2 is disposed on the first substrate 1, at a position corresponding to the second groove. The protective layer 3 covering the organic light emitting diode device 2 is formed, and details may refer to the description in the above example.

As shown in FIG. 9D, a sealing layer 4 is formed on the organic light emitting diode device 2, such that the sealing layer 4 covers the entire light emitting diode device 2 and a part of the first substrate.

As shown in FIG. 9E, the second substrate 5 formed with the sealant frame 6 and the glass adhesive 7 is pressed against the first substrate 1 such that after the second substrate 5 and the first substrate 1 are pressed together with respect to each other, the organic light emitting diode device 2 is located in the second groove. The formation of the sealant frame 6 and the glass adhesive 7 of this embodiment is the same as the method in the above example. After the sealant frame 6 and the glass adhesive 7 are cured, the organic light emitting diode package structure as shown in FIG. 9F is formed. The structures, methods, and effects not mentioned in this example are the same as those in the above example.

Various embodiments of the present disclosure and different technical features in various embodiments may be combined with each other to obtain new embodiments without conflict.

The above description is merely exemplary embodiments of the present disclosure and is not intended to limit the scope of the present disclosure. The protection scope of the present disclosure is determined by the appended claims.

What is claimed is:

1. An organic light emitting diode package structure comprising:
a first substrate;
a second substrate opposite to the first substrate; and
an organic light emitting diode device disposed between the first substrate and the second substrate,
wherein a groove is disposed on at least one of the first substrate and the second substrate, the groove is disposed on at least one of a surface of the first substrate facing the second substrate and a surface of the second substrate facing the first substrate, and the organic light emitting diode device is sealed in the groove.

2. The organic light emitting diode package structure of claim 1, wherein the groove comprises a first groove disposed on the first substrate, and the organic light emitting diode device is disposed in the first groove.

3. The organic light emitting diode package structure of claim 1, wherein the groove comprises a first groove disposed on the first substrate, and a second groove disposed on the second substrate at a position corresponding to the first groove, and the first groove and the second groove are opposite to each other, and
wherein at least a first part of the organic light emitting diode device is located in the first groove.

4. The organic light emitting diode package structure of claim 3, wherein a second part of the organic light emitting diode device is located in the second groove.

5. The organic light emitting diode package structure of claim 2, wherein a surface of the organic light emitting diode device facing the second substrate is substantially flush with a surface of the first substrate facing the second substrate.

6. The organic light emitting diode package structure of claim 1, further comprising:
a protective layer disposed over the organic light emitting diode device and covering the organic light emitting diode device.

7. The organic light emitting diode package structure of claim 6, wherein a material of the protective layer comprises one of a metal oxide and a non-metal oxide.

8. The organic light emitting diode package structure of claim 1, further comprising:
a sealing layer filled between the organic light emitting diode device and the first and second substrates, and covering the organic light emitting diode device.

9. The organic light emitting diode package structure of claim 1, further comprising:
a sealant frame disposed between the first substrate and the second substrate and bonding the first substrate and the second substrate.

10. The organic light emitting diode package structure of claim 9, further comprising:
a glass adhesive disposed between the first substrate and the second substrate at a side of the sealant frame close to an edge of the second substrate, and bonding the first substrate and the second substrate.

11. The organic light emitting diode package structure of claim 1, wherein the first substrate is a base substrate, and the second substrate is a package cover.

12. An electronic device comprising the organic light emitting diode package structure of claim 1.

13. The electronic device of claim 12, wherein the groove comprises a first groove disposed on the first substrate, and the organic light emitting diode device is disposed in the first groove.

14. The electronic device of claim 12, wherein the groove comprises a first groove disposed on the first substrate, and a second groove disposed on the second substrate at a position corresponding to the first groove, and the first groove and the second groove are opposite to each other, and
wherein at least a first part of the organic light emitting diode device is located in the first groove.

15. A packaging method comprising:
providing a first substrate and a second substrate;
forming a groove on at least one of the first substrate and the second substrate, wherein the groove is disposed on at least one of a surface of the first substrate facing the second substrate and a surface of the second substrate facing the first substrate;
providing an organic light emitting diode device on the first substrate; and
pressing the second substrate and the first substrate together such that the organic light emitting diode device is encapsulated in the groove.

16. The packaging method of claim 15, wherein the step of forming a groove on at least one of the first substrate and the second substrate comprises:
forming the groove on the first substrate.

17. The packaging method of claim 15, wherein the step of forming a groove on at least one of the first substrate and the second substrate comprises:
forming the groove on the second substrate.

18. The packaging method of claim 15, wherein the step of forming a groove on at least one of the first substrate and the second substrate comprises:
forming a first groove on the first substrate; and
forming a second groove on the second substrate at a position corresponding to the first groove.

19. The packaging method of claim 15, further comprising:
forming a sealing layer on the organic light emitting diode device such that the sealing layer is filled between the organic light emitting diode device and the first and second substrates, and covers the organic light emitting diode device.

20. The packaging method of claim 15, further comprising:
forming a sealant frame and a glass adhesive in a peripheral region of the second substrate;
melting the glass adhesive; and
curing the sealant frame and the glass adhesive.
